(19) United States
(12) Patent Application Publication
(10) Pub. No.: US 2004/0058550 A1
(43) Pub. Date: Mar. 25, 2004

(54) Dummy patterns for reducing proximity effects and method of using same

(75) Inventors: Tobias Mono, Dresden (DE); Veit Klee, Pleasant Valley, NY (US); Paul Wensley, Poughquag, NY (US); Martin Commons, Stormville, NY (US)

Correspondence Address: F. CHAU & ASSOCIATES, LLP, Suite 501, 1900 Hempstead Turnpike, East Meadow, NY, 11554, US

(73) Assignee: Infineon Technologies North America Corp.

(21) Appl. No.: 10/247,204

(22) Filed: Sep. 19, 2002

(51) Int. Cl. H01L 21/302; H01L 21/461

(52) U.S. Cl. 438/708

(57) ABSTRACT

Disclosed is an optical lithographic mask having one or more dummy patterns, each said dummy pattern having a masked area of said optical lithographic mask separated from one or more feature masked areas on said optical lithographic mask by an unmasked region of width d, wherein said width d is selected to substantially minimize an average deviation between the dimensions of said feature masked areas and corresponding features etched out upon a semiconductor surface utilizing said optical lithographic mask.

### FIELD OF THE INVENTION

This invention relates to a process for reducing proximity effects in the manufacture of semiconductors, namely the use of a dummy pattern on a mask.

### BACKGROUND OF THE INVENTION

In the semiconductor manufacturing art, the resolutions obtainable using optical lithography techniques is limited by what is known in the art as “proximity effects.” Proximity effects result in variations in feature linewidths, alterations in 2-D pattern shapes, closed contacts or holes, and shortened or rounded lines, among other distortions. For example, a rectangle may lithograph as an oval because proximity effects will tend to round off edges. Proximity effects, as their name implies, is a function of the proximity of the feature in question with other adjacent features and occurs when the features are smaller than the wavelength of the lithographing light.

The most common techniques to alleviate proximity effects are the use of phase-shifting masks and optical proximity correction (OPC).

Phase shifting utilizes chrome on glass masks to cause incident light to be shifted 180° out of phase at the edges of the features so as to cancel out proximity effects. Phase-shifters on the mask appear as rectangles separated by a regulator segment of chrome. Phase-shifting techniques allow details to be imaged down to about one-third to one-half the wavelength of the exposing light.

OPC techniques utilize the addition of enlarged features on the mask pattern so as to anticipate and correct for the proximity effects. For example, to correct for shortening and rounding of the tip of a line feature, a hammerhead shape may be provided at the tip of the line feature on the mask. The result is that the rounding and shortening proximity effect causes a relatively normal line to be imaged in photoresist. Rounding of corners on shapes is corrected by OPC by addition or subtraction of serif shapes so as to produce corners closer to the intended layout.

Phase shifting techniques are limited to detail down to about one-third to one-half wavelength of the imaging light. OPC techniques are limited by the size of the added shapes, because the mask cannot have adjacent features any closer than the width of corrective shapes added to them. What is needed is method of alleviating proximity effects without the use of appended shapes and which permits easy plug-in solutions with low correction data volume.

### SUMMARY OF THE INVENTION

Disclosed is a dummy pattern, comprising an opaque area of an optical lithographic mask separated from one or more feature opaque areas on said optical lithographic mask by a transparent region of width d, and wherein said width d is selected to substantially minimize an average deviation between the dimensions of said feature opaque areas and corresponding features patterned upon a semiconductor surface utilizing said optical lithographic mask.

In another aspect of the dummy pattern, said distance d is between about 0.25 and about 0.5 microns.

In another aspect of the dummy pattern, said distance d is about 0.3 microns.

Disclosed is a dummy pattern, comprising a transparent area of an optical lithographic mask separated from one or more feature transparent areas on said optical lithographic mask by an opaque region of width d, and wherein said width d is selected to substantially minimize an average deviation between the dimensions of said feature transparent areas and corresponding features patterned upon a semiconductor surface utilizing said optical lithographic mask.

In another aspect of the dummy pattern, said distance d is between about 0.25 and about 0.5 microns.

In another aspect of the dummy pattern, said distance d is about 0.3 microns.

Disclosed is an optical lithographic mask, comprising one or more dummy patterns, each said dummy pattern comprising a masked area of said optical lithographic mask separated from one or more feature masked areas on said optical lithographic mask by an unmasked region of width d, and wherein said width d is selected to substantially minimize an average deviation between the dimensions of said feature masked areas and corresponding features etched out upon a semiconductor surface utilizing said optical lithographic mask.

In another aspect of the optical lithographic mask, said distance d is between about 0.25 and about 0.5 microns.

In another aspect of the optical lithographic mask, said distance d is about 0.3 microns.

Disclosed is a method of optically etching features upon a semiconductor surface, comprising the steps of providing an optical lithographic mask comprising one or more dummy patterns, each said dummy pattern comprising a masked area of said optical lithographic mask separated from one or more feature masked areas on said optical lithographic mask by an unmasked region of width d, and wherein said width d is selected to substantially minimize an average deviation between the dimensions of said feature masked areas and corresponding features etched out upon the semiconductor surface utilizing said optical lithographic mask.

In another aspect of the method, said distance d is between about 0.25 and about 0.5 microns.

In another aspect of the method, said distance d is about 0.3 microns.

### BRIEF DESCRIPTION OF THE DRAWINGS

FIG. 1 shows an embodiment of a dummy pattern of the invention.

FIG. 2 shows, for seven different design dimensions, the deviation between the width of design dimensions on the mask and the actual features as etched on the vertical axis plotted against the distance d between the dummy pattern and adjacent features on the mask.

### DETAILED DESCRIPTION OF PREFERRED EMBODIMENTS

It is found that by providing a dummy pattern on a lithographic mask spaced a predetermined distance from features suffering proximity effects, that such proximity effects are substantially reduced.

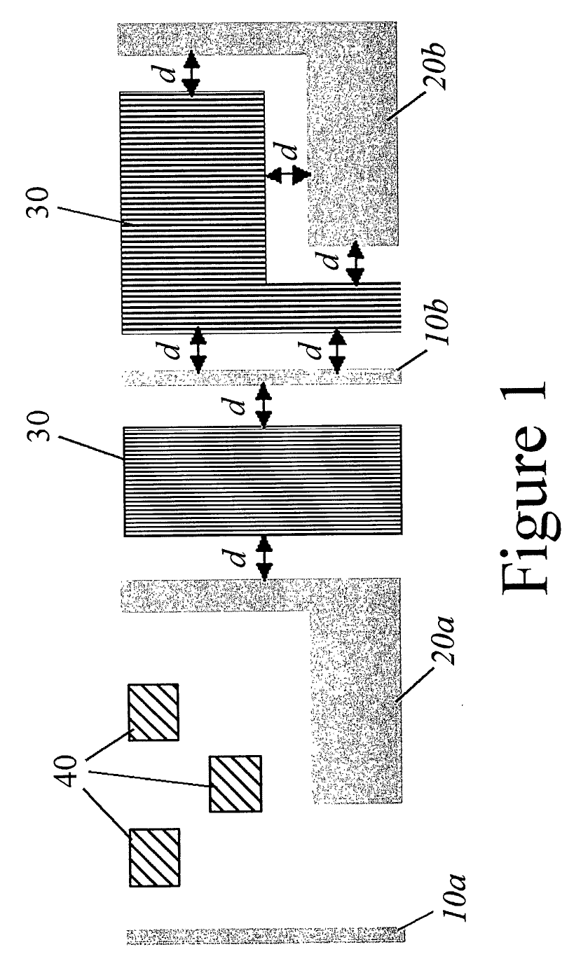

Referring to FIG. 1, there is shown a mask pattern 1 comprising a plurality of narrow lines 10a, 10b, shaped features 20a, 20b, and some typical fill patterns 40. Fill patterns are generated after completion of the chip design and added to the chip design data to achieve homogenous etch loading across the whole chip. In some cases, as shown here, they may take up enough space to block use of the dummy patterns of this invention. These features represent raised portions of the developed photoresist, while the white spaces between them in the drawing represent depressions or spaces formed by the lithographic imaging process.

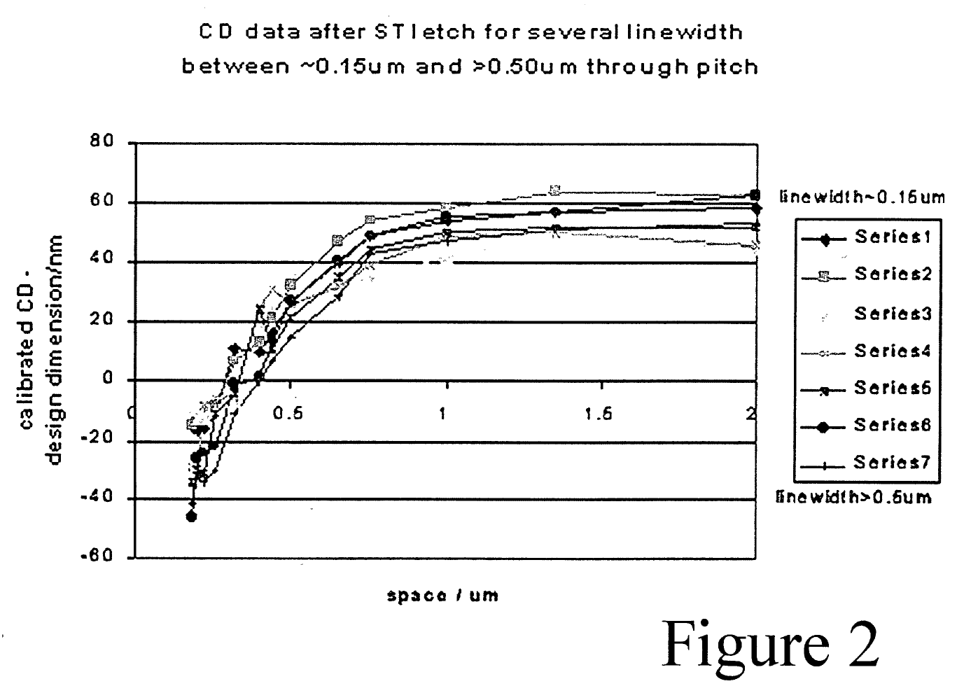

Also provided is a dummy pattern 30 of the invention. The dummy pattern 30 is sized and positioned to fill in a space between adjacent features, in this example the adjacent features are a vertical line 10b and a shaped feature 20b. The dummy pattern 30 is spaced from these features by a distance d that is selected according to the wavelength of lithographing light used. This may be determined experimentally, as can be seen in FIG. 2 for a typical patterning wavelength of 248 nm.

Referring to FIG. 2, we see the actual experimental results from a combined patterning process via lithography and etch. Lithography is an image transfer in photoresist, etch is a pattern transfer from photoresist into silicon via. Photoresist has a masking function, whereas unetched Silicon has to be left after an etch process. Seven different lines were measured where the design dimension (i.e., the average width of a transistor active area) varied from 0.15 to 0.5 microns. The spacing d between the dummy patterns and adjacent feature masked areas varies between about 0.2 and 2 microns and the results graphed against the average deviation between the widths of features as designed on the mask and as actually etched. Of course, the optimal result would be zero on the vertical axis, meaning there is no difference between the features in design and as actually etched. A negative value on the vertical axis indicates that the etched features are smaller than as masked, while positive values indicate the reverse.

As can be seen in FIG. 2, the optimal distance d between the dummy pattern and adjacent mask features is between about 0.25 and about 0.5 microns, preferably about 0.3 microns at a wavelength of 248 nm.

Preferably, the total width of the dummy pattern will be greater than the minimum ground rule, if only slightly, because larger patterns are usually easier to image, especially if the pattern dimensions are less than the wavelength of the imaging light source.

In the example shown, the dummy pattern is about 0.18 micrometers wide and spaced 0.3 from the features 10b, 20b. After etching, it is found that the critical dimension of the active area (AA) etched on the semiconductor surface is substantially identical to that patterned on the mask and depth and sidewall taper variations in single trench isolations are substantially reduced.

The invention works because of optical proximity behavior in lithographic sub-wavelength patterning of photoresist. If the wavelength is used for lithographic imaging is below the transferred image dimension, optical proximity effects occur, the result of constructive and destructive interference.

It is to be understood that all physical quantities disclosed herein, unless explicitly indicated otherwise, are not to be construed as exactly equal to the quantity disclosed, but rather as about equal to the quantity disclosed. Further, the mere absence of a qualifier such as “about” or the like, is not to be construed as an explicit indication that any such disclosed physical quantity is an exact quantity, irrespective of whether such qualifiers are used with respect to any other physical quantities disclosed herein.

While preferred embodiments have been shown and described, various modifications and substitutions may be made thereto without departing from the spirit and scope of the invention. Accordingly, it is to be understood that the present invention has been described by way of illustration only, and such illustrations and embodiments as have been disclosed herein are not to be construed as limiting to the claims.

What is claimed is:

1. A dummy pattern, comprising:
an opaque area of an optical lithographic mask separated from one or more feature opaque areas on said optical lithographic mask by a transparent region of width d; and
wherein said width d is selected to substantially minimize an average deviation between the dimensions of said feature opaque areas and corresponding features patterned upon a semiconductor surface utilizing said optical lithographic mask.

2. The dummy pattern of claim 1 wherein said distance d is between about 0.25 and about 0.5 microns.

3. The dummy pattern of claim 1 wherein said distance d is about 0.3 microns.

4. A dummy pattern, comprising:
a transparent area of an optical lithographic mask separated from one or more feature transparent areas on said optical lithographic mask by an opaque region of width d; and
wherein said width d is selected to substantially minimize an average deviation between the dimensions of said feature transparent areas and corresponding features patterned upon a semiconductor surface utilizing said optical lithographic mask.

5. The dummy pattern of claim 4 wherein said distance d is between about 0.25 and about 0.5 microns.

6. The dummy pattern of claim 4 wherein said distance d is about 0.3 microns.

7. An optical lithographic mask, comprising:
one or more dummy patterns, each said dummy pattern comprising a masked area of said optical lithographic mask separated from one or more feature masked areas on said optical lithographic mask by an unmasked region of width d; and
wherein said width d is selected to substantially minimize an average deviation between the dimensions of said feature masked areas and corresponding features etched out upon a semiconductor surface utilizing said optical lithographic mask.

8. The optical lithographic mask of claim 7 wherein said distance d is between about 0.25 and about 0.5 microns.

9. The optical lithographic mask of claim 7 wherein said distance d is about 0.3 microns.

10. A method of optically etching features upon a semiconductor surface, comprising the steps of:
providing an optical lithographic mask comprising one or more dummy patterns, each said dummy pattern comprising
a masked area of said optical lithographic mask separated from one or more feature masked areas on said optical lithographic mask by an unmasked region of width d; and
wherein said width d is selected to substantially minimize an average deviation between the dimensions of said feature masked areas and corresponding features etched out upon the semiconductor surface utilizing said optical lithographic mask.

11. The method of claim 10 wherein said distance d is between about 0.25 and about 0.5 microns.

12. The method of claim 10 wherein said distance d is about 0.3 microns.
